(19) United States
(12) Patent Application Publication
(10) Pub. No.: US 2016/0266482 A1
(43) Pub. Date: Sep. 15, 2016

(54) GLASS SUBSTRATE FOR MASK BLANK

(71) Applicant: ASAHI GLASS COMPANY, LIMITED, Chiyoda-ku (JP)

(72) Inventors: Naohiro UMEO, Fukushima (JP); Yoshiaki IKUTA, Tokyo (JP); Yuzo OKAMURA, Tokyo (JP)

(73) Assignee: ASAHI GLASS COMPANY, LIMITED, Chiyoda-ku (JP)

(21) Appl. No.: 15/052,300

(22) Filed: Feb. 24, 2016

(30) Foreign Application Priority Data
Mar. 10, 2015 (JP) 2015-047085

(51) Int. Cl. G03F 1/22

(52) U.S. Cl. CPC G03F 1/22

(57) ABSTRACT

A glass substrate for a mask blank includes two main surfaces facing each other, side surfaces and surfaces to be chamfered. The surfaces to be chamfered are provided peripherally around each of the two main surfaces. At least one of the side surfaces and the surfaces to be chamfered in the glass substrate has, in a measurement area with an atomic force microscope (AFM) of 3 μm square, an arithmetic mean roughness (Ra) of 0.5 nm or less and a dale void volume (Vᵥᵥ) obtained from a bearing area curve as defined in ISO 25178-2(2012) of 1.5×10⁷ nm³ or less.

### CROSS-REFERENCE TO RELATED APPLICATIONS

This application claims priority from Japanese Patent Application No. 2015-047085 filed on Mar. 10, 2015, the entire subject matter of which is incorporated herein by reference.

### BACKGROUND OF THE INVENTION

1. Technical Field

The present invention relates to a glass substrate for a mask blank for use in various kinds of lithography. The glass substrate for a mask blank in the present invention is favorable for a glass substrate for mask blanks to be used in lithography using EUV (extreme ultraviolet) light (hereinafter abbreviated as “EUVL”) (hereinafter this glass substrate is abbreviated as “glass substrate for EUVL mask blank”).

The glass substrate for a mask blank in the present invention is also favorable for a glass substrate for mask blanks for use in lithography using an already-existing transmission optical system, for example, for a glass substrate for mask blanks for lithography using an ArF excimer laser or a KrF excimer laser.

2. Background Art

With the recent tendency toward high-density and high-precision ultra-LSI devices, the specifications required for the surface of the glass substrate for mask blanks for use in various kinds of lithography are becoming severer year by year. In particular, with the wavelength of the light from the exposing source being shorter, the requirements for the profile accuracy (flatness) of the substrate surface and for the absence of the defects (particles, scratches, pits, etc.) in the surface are becoming severer, and a glass substrate having an extremely high degree of flatness and having few microdefects is desired.

For example, in a case of immersion lithography using an ArF excimer laser as the light from an exposing source, the necessary flatness of the glass substrate surface for mask blanks is 350 nm or less and the necessary defect size in the glass substrate surface is 70 nm or less; and further in a case of a glass substrate for EUVL mask blanks, the necessary flatness of the glass substrate surface is 100 nm or less as the PV value, and the necessary defect size is 50 nm or less.

To attain the above-mentioned high-level flatness, the surface of a glass substrate for mask blanks undergoes high-precision polishing. In this polishing, the surface of a glass substrate for mask blanks is pre-polished at a relatively high processing rate to have a predetermined flatness, and then finally polished to have a desired flatness, using a method of higher processing precision or under a processing condition capable of attaining a higher processing accuracy.

Patent Document 1 shows one example of a process of the above-mentioned pre-polishing and final polishing. According to the method described in Patent Document 1, the surface of a glass substrate is pre-polished using a polisher including a polishing agent containing cerium oxide as the main ingredient and a polishing pad, and then finally polished with colloidal silica.

In the outer peripheral part of the surface of a glass substrate for mask blanks, surfaces to be chamfered are provided for the reason of preventing cracking or chipping.

The above-mentioned requirements for flatness and defect size relate to the main surface excepting the outer peripheral part in which surfaces to be chamfered are provided, among the surfaces of a glass substrate for mask blanks.

On the other hand, the requirement for the side surfaces and the surfaces to be chamfered in a glass substrate for mask blanks in point of the profile accuracy (flatness) and the defects (particles, scratches, pits, etc.) is not so serious, unlike the case of the main surfaces of the glass substrate for mask blanks. Accordingly, after a glass substrate has been cut to have a predetermined shape and a predetermined size, the side surfaces and the surfaces to be chamfered in the glass substrate are brush-polished and then the main surfaces of the glass substrate are finally polished (Patent Documents 2 and 3).

However, brush-polishing may enlarge the surface roughness of the side surfaces and the surfaces to be chamfered in the glass substrate, and therefore relatively large recesses may be formed in these faces. As the case may be, the polishing agent used when the main surfaces of the glass substrate are finally polished may deposit in the recesses existing in the side surfaces and the surfaces to be chamfered in the glass substrate. After the final polishing of the main surfaces of the glass substrate, the glass substrate is washed, but during the washing, the polishing agent could not be removed completely but may remain in the recesses, and afterwards, the polishing agent may drop off from pits or scratches to form defects (particles, scratches, pits, etc.) in the main surfaces of the glass substrate for mask blanks.

In Patent Document 4, after the side surfaces and the surfaces to be chamfered in a glass substrate have been mirror-polished so as to have an arithmetic mean surface roughness Ra of 0.5 nm or less, the main surfaces of the glass substrate are mirror-polished to have an arithmetic mean surface roughness Ra of 0.2 nm or less, thereby preventing defects (particles, scratches, pits, etc.) in the main surfaces of the glass substrate for mask blanks.

Patent Document 1: JP-A-S64-40267

Patent Document 2: Japanese Patent No. 2585727

Patent Document 3: Japanese Patent No. 2866684

Patent Document 4: Japanese Patent No. 4784969

### SUMMARY OF THE INVENTION

However, it has been found that, even in a case where the side surfaces and the surfaces to be chamfered in a glass substrate have been mirror-polished and then the main surfaces of the glass substrate are mirror-polished, like in the invention described in Patent Document 4, the defects (particles, scratches, pits, etc.) in the main surfaces of the glass substrate could not still be prevented in some cases.

For solving the above-mentioned problems in the related art, the present invention provides a glass substrate for a mask blank which can prevent the defects in the main surfaces.

The present invention provides a glass substrate for a mask blank, including two main surfaces facing each other, side surfaces and surfaces to be chamfered, the surfaces to be chamfered being provided peripherally around each of the two main surfaces, wherein:

at least one of the side surfaces and the surfaces to be chamfered in the glass substrate has, in a measurement area with an atomic force microscope (AFM) of 3 μm square, an arithmetic mean roughness (Ra) of 0.5 nm or less and a dale void volume (Vᵥᵥ) obtained from a bearing area curve as defined in ISO 25178-2(2012) of 1.5×10⁷ nm³ or less.

In the glass substrate for a mask blank, a flatness of at least one of the main surfaces is preferably 350 nm or less as PV value.

In the glass substrate for a mask blank, a flatness of at least one of the main surfaces is preferably 100 nm or less as PV value.

In the glass substrate for mask blanks in the present invention, the polishing agent used in finally polishing the main surfaces of the glass substrate can be prevented from being trapped in the recesses existing in the side surfaces and the surfaces to be chamfered in the glass substrate. Therefore, the polishing agent used in final polishing and trapped in recesses in washing the polished glass substrate can be prevented from moving toward and adhering to the main surfaces of the glass substrate. Consequently, the defects in the main surfaces of the glass substrate for mask blanks can be prevented.

### DETAILED DESCRIPTION OF THE INVENTION

The glass substrate for mask blanks in the present invention includes two main surfaces facing each other, side surfaces and surfaces to be chamfered, and the surfaces to be chamfered are provided peripherally around each of the main surfaces. The width of the surface to be chamfered may differ depending on the specifications of the glass substrate, and in a case of a glass substrate having a size of 152 mm square for use as a glass substrate for mask blanks, the width may be from 0.2 to 0.6 mm.

In the glass substrate for mask blanks in the present invention, the surface profile of at least one of the side surfaces and the surfaces to be chamfered satisfies the following (1) and (2) in a measurement area with an atomic force microscope (AFM) of 3 μm square.

(1) The arithmetic mean roughness (Ra) (hereinafter this is referred to as “Ra” in this specification) is 0.5 nm or less.

(2) The dale void volume (Vᵥᵥ) obtained from the bearing area curve as defined in ISO 25178-2 (2012) (hereinafter this is referred to as “Vᵥᵥ” in this specification) is 1.5×10⁷ nm³ or less.

The glass substrate for mask blanks in the present invention satisfies the above-mentioned (1) and (2) in point of the surface profile of at least one of the side surfaces and the surfaces to be chamfered thereof in a measurement area with an atomic force microscope (AFM) of 3 μm square, and therefore defects in the main surfaces of the glass substrate for mask blanks can be prevented.

As described above, the above (1) has been noted in Patent Document 4. However, it has now been found that, even in a case where the side surfaces and the surfaces to be chamfered in a glass substrate for mask blanks are polished to have Ra of 0.5 nm or less, and then the main surfaces of the glass substrate are finally polished, some defects (particles, scratches, pits, etc.) in the main surfaces of the glass substrate could not be still prevented in some cases.

The present inventors have assiduously studied these problems and, as a result, they have found that the fine surface profile that could not be actualized by Ra, concretely, the fact that the polishing agent used for finally polishing the main surfaces of a glass substrate is trapped in the minute recesses existing in the side surfaces or the surfaces to be chamfered thereof, and the fact that in washing the glass substrate after polishing, the polishing agent trapped in the recesses moves toward and adheres to the main surfaces of the glass substrate, are the factors to cause the defects (particles, scratches, pits, etc.) in the main surfaces of the glass substrate. In addition, the present inventors have found that the minute recesses can be evaluated by Vᵥᵥ.

In the glass substrate for mask blanks in the present invention, Vᵥᵥ of at least one of the side surfaces and the surfaces to be chamfered is 1.5×10⁷ nm³ or less in the measurement area with an atomic force microscope (AFM) of 3 μm square, and therefore, the polishing agent used in finally polishing the main surfaces of the glass substrate can be prevented from being trapped in the recesses existing in the side surfaces or the surfaces to be chamfered in the glass substrate. Therefore, the polishing agent used in final polishing can be readily removed by washing the polished glass substrate. Consequently, the defects in the main surfaces of the glass substrate for mask blanks can be prevented.

Vᵥᵥ of at least one of the side surfaces and the surfaces to be chamfered is 1.5×10⁷ nm³ or less, and this is because when the polishing agent can be prevented from being trapped in the recesses existing in at least one of the side surfaces and the surfaces to be chamfered, the effect of preventing the defects (particles, scratches, pits, etc.) in the main surfaces of the glass substrate are exhibited.

In the glass substrate for mask blanks in the present invention, it is desirable that, of the side surfaces and the surfaces to be chamfered thereof, Vᵥᵥ of the side surfaces is 1.5×10⁷ nm³ or less from the viewpoint of preventing the defects in the main surfaces of the glass substrate for mask blanks.

In addition, in the glass substrate for mask blanks in the present invention, it is more desirable that Vᵥᵥ of both the side surfaces and the surfaces to be chamfered is 1.5×10⁷ nm³ or less from the viewpoint of preventing the defects in the main surfaces of the glass substrate for mask blanks.

Ra and Vᵥᵥ of at least one of the side surfaces and the surfaces to be chamfered in the glass substrate for mask blanks can be measured by using an atomic force microscope (AFM). In Examples given hereinunder, Ra and Vᵥᵥ of the side surfaces of the glass substrate for mask blanks were measured in a measurement area with AFM of 3 μm square.

In the glass substrate for mask blanks in the present invention, Ra of at least one of the side surfaces and the surfaces to be chamfered is preferably 0.2 nm or less, more preferably 0.1 nm or less.

In the glass substrate for mask blanks in the present invention, Vᵥᵥ of at least one of the side surfaces and the surfaces to be chamfered is preferably 1.0×10⁷ nm³ or less, more preferably 5.0×10⁶ nm³ or less.

In the glass substrate for mask blanks in the present invention, the flatness of the main surfaces is required to satisfy a requirement value depending on the use thereof.

In a case where the glass substrate for mask blanks in the present invention is used in immersion lithography using an ArF excimer laser as the exposing source, the flatness of the main surfaces thereof is preferably 350 nm or less as the PV value, more preferably 300 nm or less as the PV value, even more preferably 250 nm or less as the PV value.

On the other hand, in a case where the glass substrate for mask blanks in the present invention is used as a glass substrate for EUVL mask blanks, the flatness of the main surfaces thereof is preferably 100 nm or less as the PV value, more preferably 80 nm or less as the PV value, even more preferably 60 nm or less as the PV value.

The flatness of the glass substrate for mask blanks can be measured by using laser interferometer, contact-type surface profile analyzer or the like. In particular, the laser interferometer is preferable because the whole of the main surface of the substrate can be measured at one time without contacting with the main surface. Among them, a device which is sold for measuring the flatness of a mask blank or substrate for mask blank, e.g. UltraFlat (manufactured by Corning Tropel Corporation) and Verifire (manufactured by Zygo Corporation), may be used.

Preferably, the glass constituting the glass substrate for mask blanks in the present invention has a small coefficient of thermal expansion and the dispersion of the coefficient of thermal expansion thereof is small. Concretely, low-thermal expansion glass having an absolute value of a coefficient of thermal expansion at 20° C. of 600 ppb/° C. is preferable, ultra-low-thermal expansion glass having a coefficient of thermal expansion at 20° C. of 400 ppb/° C. is more preferable, ultra-low-thermal expansion glass having a coefficient of thermal expansion at 20° C. of 100 ppb/° C. is even more preferable, and one having 30 ppb/° C. is still more preferable.

As the above-mentioned low-thermal expansion glass and ultra-low-thermal expansion glass, glass mainly containing SiO₂, typically synthetic quartz glass is usable. Concretely, examples thereof include synthetic quartz glass, AQ series (synthetic quartz glass manufactured by Asahi Glass Company, Ltd.), synthetic quartz glass mainly containing SiO₂ and containing from 1 to 12% by mass of TiO₂, and AZ (Zero-expansion glass manufactured by Asahi Glass Company, Ltd.).

The glass substrate for mask blanks in the present invention having the characteristic features mentioned above can be produced according to the following process.

In general, in a production process for glass substrates for mask blanks, the main surface of the glass substrate is pre-polished plural times, and then finally polished. During the pre-polishing, the glass substrate is roughly polished to have a predetermined thickness, followed by subjecting to side face polishing and chamfering process, and moreover, both the main surfaces are pre-polished so that the surface roughness and the flatness thereof could be not more than a predetermined value. The pre-polishing is carried out plural times, for example, two or three times. A conventional method may be employed for the pre-polishing. For example, plural two-side lapping devices are connected in series, and a glass substrate is sequentially polished in the polishing device while the polishing agent to be used and the polishing condition are changed, whereby the main surfaces of the glass substrate are pre-polished so as to have a predetermined surface roughness and a predetermined flatness.

Also in the present invention, it is desirable that the main surfaces of the glass substrate are pre-polished so as to have a predetermined surface roughness and a predetermined flatness. It is desirable that the main surfaces of the glass substrate are pre-polished so that the flatness (PV value) thereof could be 1 μm or less, more preferably 500 nm or less.

Next, the glass substrate for mask blanks is polished according to the process mentioned below so that Ra and Vᵥᵥ of at least one of the side surfaces and the surfaces to be chamfered thereof could satisfy the above-mentioned requirements.

As a polishing cloth, one prepared by fixing a grinding stone on a film, referred to as a lapping tape, or a soft nonwoven fabric or urethane pad is used. Preferably, the soft nonwoven fabric or urethane pad has an Asker-C hardness of 80 or less.

In a case where a lapping tape is used, polishing grains exist on the film, and therefore the glass substrate is polished in pure water. Concretely, while a lapping tape is kept in contact with at least one of the side surfaces and the surfaces to be chamfered in pure water, the lapping tape and the glass substrate are moved relatively to polish the glass substrate.

In a case where a soft nonwoven fabric or urethane pad is used, a glass substrate is polished in slurry of polishing grains dispersed in pure water. Concretely, a nonwoven fabric or urethane pad is kept in a state of pressing against at least one of the side surfaces and the surfaces to be chamfered of a glass substrate immersed in the slurry of polishing grains dispersed in pure water, and the nonwoven fabric or urethane pad and the glass substrate are moved relatively to polish the glass substrate.

Here, when the glass substrate or the polishing cloth (lapping tape, or soft nonwoven fabric or urethane pad) is dried, the abrasive grains may damage the glass substrate so that the value of Vᵥᵥ may increase, and therefore it is desirable that the glass substrate and the polishing cloth are always kept wet.

Preferably, the polishing treatment according to the above-mentioned process is carried out for 3 minutes or more.

As ordinary polishing grains, examples thereof include diamond, silicon carbide, aluminium oxide, chromium oxide, cerium oxide, zirconium oxide, colloidal silica and the like, but in the case of polishing grains except cerium oxide and colloidal silica, the polishing grains may damage the glass substrate so that the value of Vᵥᵥ may increase, and therefore it is desirable to use cerium oxide having a chemical polishing effect or colloidal silica having a small particle size. Regarding the size of the polishing grains, when the size is too large, the value of Ra may increase, and therefore in order that Ra could be 0.5 nm or less, it is desirable that the particle size is 1 μm or less. More preferably, the particle size is 0.5 μm or less, but when the particle size is too small, the polishing time would be too long, and therefore, the particle size is preferably 0.015 μm or more. Using the polishing grains mentioned above, Vᵥᵥ can be 1.0×10⁷ nm³ or less.

Next, the main surfaces of the glass substrate for mask blanks are finally polished so as to have a desired flatness. For the final polishing, it is desirable to use a polishing pad and polishing slurry. As the polishing pad to be used in polishing the main surfaces of the glass substrate for mask blanks, examples thereof include a polishing pad having a polyurethane resin foam layer produced by infiltrating a polyurethane resin into a base fabric such as a nonwoven fabric followed by subjecting it to wet-process solidification treatment. The polishing pad is preferably a suede-based polishing pad. For the suede-based polishing pad, a soft resin foam having a suitable modulus of compressive elasticity is preferably used, and concrete examples thereof include ether-based resin foams, ester-based resin foams, carbonate-based resin foams and the like.

The polishing slurry for use for polishing the main surfaces of the glass substrate for mask blanks contains polishing grains and a dispersion medium for them. Colloidal silica, cerium oxide or the like is preferred. Colloidal silica is especially preferred as capable of polishing the glass substrate more accurately.

Examples of the dispersion medium for polishing grains include water and organic solvents, and water is preferred.

On the glass substrate for mask blanks after final polishing, the polishing agent (polishing grains) used in final polishing may remain. Therefore, for the purpose of removing the polishing agent remaining on the glass substrate for mask blanks, it is desirable that the glass substrate for mask blanks is washed in wet. As the wet washing to be carried out for this purpose, examples thereof include physical washing such as scrub washing, ultrasonic washing, jet washing (washing with high-pressure water), and chemical washing using an acid or alkaline washing liquid.

### EXAMPLES

The present invention is described in detail by Examples hereinunder. Examples 1 to 3 are comparative examples, and Examples 4 to 6 are examples of the present invention.

### Example 1

In this Example, the following process was carried out.

A synthetic quartz glass substrate having a size of 152 mm square and a thickness of 6.6 mm was prepared. In the synthetic quartz glass substrate, the size of the main surfaces is 151.2 mm square and the width of the surfaces to be chamfered is 0.4 mm.

Using a double-side lapping device, the main surfaces of the synthetic quartz glass substrate were pre-polished so that the flatness (PV value) of the main surfaces could be 1 μm or less.

Next, the side surfaces of the synthetic quartz glass substrate were polished according to the following process.

While a lapping tape (substrate PET) with silicon carbide abrasive grains (particle size 0.5 μm) fixed thereto was kept in a state of pressing against the side surfaces of the synthetic quartz glass substrate under a pressure of 0.1 MPa in air, the lapping tape and the glass substrate were moved relatively to polish the glass substrate. Concretely, while the lapping tape was fixed, the glass substrate was oscillated 20 times per one side of the glass substrate, taking 3 minutes.

Next, using a soft polyurethane-made polishing pad as a polishing pad and using colloidal silica as a polishing slurry, the main surfaces of the synthetic quartz glass substrate were polished.

After the synthetic quartz glass substrate was washed in wet, the number of concave and convex defects having a silica particles-equivalent size of 70 nm or more in an area of 132 mm square of the main surfaces of the synthetic quartz glass substrate was counted, using an automatic fault detector M1350 manufactured by Lasertec. The results are shown in the following Table.

After the fault detection, an arbitrary area of 3 μm square of the side surfaces of the synthetic quartz glass substrate was analyzed using an atomic force microscope (AFM) to determine Ra and Vᵥᵥ in the area. The results are shown in the following Table.

### Example 2

The same process as in Example 1 was carried out except that the polishing of the side surfaces of the synthetic quartz glass substrate was conducted according to the following process.

Using polishing slurry prepared by dispersing cerium oxide (particle size 1.2 μm) in pure water, the side surfaces of the synthetic quartz glass substrate were kept in contact with a rotating nylon brush and the nylon brush and the glass substrate were moved relatively to polish the glass substrate. The thickness direction of the substrate and the rotating shaft of the nylon brush were parallel to each other, and the nylon brush was oscillated in the axial direction for 3 minutes to conduct the relative movement of the nylon brush and the glass substrate. The nylon brush was pressed against the side surfaces of the glass substrate under a pressure of 0.1 MPa.

### Example 3

The same process as in Example 1 was carried out except that the lapping tape was pressed against the glass substrate not in air but in ultrapure water.

### Example 4

The same process as in Example 1 was carried out except that, using a lapping tape with cerium oxide (particle size 0.3 μm) fixed thereto, the lapping tape was pressed against the glass substrate not in air but in ultrapure water.

### Example 5

After the side surfaces of a synthetic quartz glass substrate were polished according to the same process as in Example, 2, and then the side surfaces of the synthetic quartz glass substrate were further polished according to the following process.

As a polishing cloth, a soft nonwoven fabric having a width of 5 cm (Asker-C hardness: 73) was used, and the nonwoven fabric was pressed against the side surfaces of the glass substrate immersed in a polishing slurry of cerium oxide (particle size 1 μm) dispersed in pure water, under a face pressure of 0.3 MPa, and the nonwoven fabric was moved 20 times back and forth, taking 3 minutes. According to the process, the glass substrate and the nonwoven fabric were relatively moved to polish the glass substrate.

### Example 6

The same process as in Example 5 was carried out except that a soft nonwoven fabric having a width of 5 cm (Asker-C hardness: 66) was used and a polishing slurry of cerium oxide (particle size 0.46 μm) dispersed in pure water was used.

TABLE 1

| | | | Number of Defects on Main Surfaces |
|---|---|---|---|
| | Side Surfaces | | (132 mm square, 70 nm or more (SiO₂ |
| | Ra (nm) | Vᵥᵥ (nm³) | spherical particles-equivalent)) |
| Example 1 | 0.72 | 3.2 × 10⁷ | 31.0 |
| Example 2 | 0.57 | 8.9 × 10⁶ | 19.4 |
| Example 3 | 0.42 | 1.7 × 10⁷ | 22.6 |
| Example 4 | 0.47 | 1.4 × 10⁷ | 14.4 |
| Example 5 | 0.38 | 6.8 × 10⁶ | 7.5 |
| Example 6 | 0.10 | 1.4 × 10⁶ | 3.7 |

As obvious from comparison between Examples 2 and 3, it was found that the number of defects on the main surface was influenced more by Vᵥᵥ of the side surfaces than by Ra thereof. In Examples 4 to 6 where Ra of the side surfaces was 0.5 nm or less and Vᵥᵥ thereof was 1.5×10⁷ nm³ or less, the number of defects on the main surfaces was much reduced.

The above Examples demonstrate that in the cases where Ra of the side surfaces is 0.5 nm or less and Vᵥᵥ thereof is 1.5×10⁷ nm³ or less, the number of defects on the main surfaces is much reduced. The other cases where Ra of the surfaces to be chamfered is 0.5 nm or less and Vᵥᵥ thereof is 1.5×10⁷ nm³ or less also provide the same result.

What is claimed is:

1. A glass substrate for a mask blank, comprising two main surfaces facing each other, side surfaces and surfaces to be chamfered, the surfaces to be chamfered being provided peripherally around each of the two main surfaces, wherein:
at least one of the side surfaces and the surfaces to be chamfered in the glass substrate has, in a measurement area with an atomic force microscope (AFM) of 3 μm square, an arithmetic mean roughness (Ra) of 0.5 nm or less and a dale void volume (Vᵥᵥ) obtained from a bearing area curve as defined in ISO 25178-2(2012) of 1.5×10⁷ nm³ or less.

2. The glass substrate for a mask blank according to claim 1, wherein a flatness of at least one of the main surfaces is 350 nm or less as PV value.

3. The glass substrate for a mask blank according to claim 1, wherein a flatness of at least one of the main surfaces is 100 nm or less as PV value.
